(19) United States
(12) Patent Application Publication
(10) Pub. No.: US 2026/0253533 A1
(43) Pub. Date: Aug. 27, 2026

(54) METHOD OF CHROMA COMPENSATION FOR PIXELS AND MICROLED DISPLAY USED IN THE SAME

(71) Applicant: RAYLEIGH VISION INTELLIGENCE CO., LTD., HSINCHU CITY (TW)

(72) Inventor: Chia-Jung LIN, HSINCHU CITY (TW)

(73) Assignee: RAYLEIGH VISION INTELLIGENCE CO., LTD., HSINCHU CITY (TW)

(21) Appl. No.: 19/547,922

(22) Filed: Feb. 24, 2026

(30) Foreign Application Priority Data
Feb. 24, 2025 (TW) 114106658

(51) Int. Cl. G09G 3/32; H10H 29/34

(52) U.S. Cl. CPC G09G 3/32; H10H 29/34; G09G 2320/0242; G09G 2360/147

(57) ABSTRACT

A method of chroma compensation for pixels is provided. The method comprises: driving the first, second and third sub-pixels in each pixel of a micro-LED display to sequentially emit light; measuring the first, second, and third dominant wavelengths separately from the first, second and third sub-pixels of each pixel; and driving the second or third sub-pixel of each pixel to emit light with partial brightness to mix with light having the first dominant wavelength emitted from the first sub-pixel within the same pixel, wherein an adjusted first dominant wavelength presented by the color matching of mixed light is closer to a minimum value, a maximum value, or a mean value among the measured first dominant wavelengths.

### CROSS-REFERENCE TO RELATED APPLICATION

This application claims priority from Taiwan Patent Application No. 114106658 filed on February 24, 2025, which are hereby incorporated herein by reference in its entirety.

### BACKGROUND OF THE INVENTION

### Field of the Invention

The present disclosure relates to a method for chroma compensation of pixels and a micro light-emitting diode (Micro-LED) display using the same, particularly to a method that uses other color lights to compensate for the primary color light and a display that employs this method.

### Description of Related Art

In the field of light-emitting diodes (LEDs), the miniaturization of conventional LEDs to the micrometer scale has given rise to micro-LEDs (μLEDs). When used in display technology, each micro-LED can serve as a sub-pixel in a display panel, and such panels are known as micro-LED displays (Micro-LED Displays). Due to their high luminous efficiency, long lifespan, and high resolution, micro-LED displays are widely regarded as a leading technology for the next generation of displays.

The epitaxial process for Micro-LEDs often uses techniques such as metal organic chemical vapor deposition (MOCVD) to grow the light- emitting structure layers on a support substrate. Variations in production conditions and raw materials during the epitaxial process can result in differences in the optical properties of each Micro-LED chip. However, the requirements for uniformity in brightness and color in Micro-LED displays are increasingly stringent, especially for head-mounted displays, where color differences in small areas are not acceptable.

Thus, after the optical characteristic testing of Micro-LED chips, some chips of certain grades or bin codes are found to be unusable, leading to a low yield rate and significantly increasing production costs. On the other hand, to make use of most of the chips of different grades or bin codes, a method is adopted where these chips are randomly placed on the display substrate, which includes drive circuits. However, this random mixing of chips can cause significant color differences between adjacent pixels when displaying a single color (e.g., all pixels showing only red light), making it easy to spot visual defects in the image.

### SUMMARY OF THE INVENTION

In one embodiment of the present disclosure, a method of chroma compensation for pixels is provided herein. The method comprises: driving a first sub-pixel, a second sub-pixel, and a third sub-pixel in each pixel of a micro-LED display to sequentially emit light; measuring a first dominant wavelength of the first sub-pixel, a second dominant wavelength of the second sub-pixel, and a third dominant wavelength of the third sub-pixel in each pixel; and driving the second sub-pixel or the third sub-pixel in each pixel to emit light with partial brightness to mix with light emitted by the first sub-pixel at the first dominant wavelength within the same pixel, wherein the color of the mixed light corresponds to an adjusted first dominant wavelength; wherein the adjusted first dominant wavelength is closer to a minimum value, a maximum value, or an average value among the measured first dominant wavelengths.

In another aspect of the present disclosure, the first sub-pixel is a red sub-pixel and the second sub-pixel is a green sub-pixel, the red sub-pixel emits red light having a red dominant wavelength, and the green sub-pixel within the same pixel emits green light with partial brightness having a green dominant wavelength so that the color of light resulting from mixing the red light and the green light corresponds to an adjusted red dominant wavelength and the adjusted red dominant wavelength is closer to the minimum value among the measured first dominant wavelengths.

In another aspect of the present disclosure, the first sub-pixel is a blue sub-pixel and the second sub-pixel is a green sub-pixel, the blue sub-pixel emits blue light having a blue dominant wavelength, and the green sub-pixel within the same pixel emits green light with partial brightness having a green dominant wavelength so that the color of light resulting from mixing the blue light and the green light corresponds to an adjusted blue dominant wavelength, and the adjusted blue dominant wavelength is closer to the maximum value among the measured first dominant wavelengths.

In another aspect of the present disclosure, the first sub-pixel is a green sub-pixel, the second sub-pixel is a blue sub-pixel, the third sub-pixel is a red sub-pixel, the green sub-pixel emits green light having a green dominant wavelength, and the blue sub-pixel within the same pixel emits blue light with partial brightness having a blue dominant wavelength so that the color of light resulting from mixing the green light and the blue light corresponds to an adjusted green dominant wavelength, and the adjusted green dominant wavelength is closer to the average value among the measured first dominant wavelengths.

In another aspect of the present disclosure, the first sub-pixel is a green sub-pixel, the second sub-pixel is a blue sub-pixel, the third sub-pixel is a red sub-pixel, the green sub-pixel emits green light having a green dominant wavelength, and the red sub-pixel within the same pixel emits red light with partial brightness having a red dominant wavelength so that the color of light resulting from mixing the green light and the red light corresponds to an adjusted green dominant wavelength, and the adjusted green dominant wavelength is closer to the average value among the measured first dominant wavelengths.

In one embodiment of the present disclosure, a micro-LED display is provided. The display comprises: a plurality of pixels, each pixel including a red sub-pixel, a green sub-pixel, and a blue sub-pixel; a storage unit configured to store a first dominant wavelength of the red sub-pixel, a second dominant wavelength of the green sub-pixel, and a third dominant wavelength of the blue sub-pixel for each pixel, and further configured to store a maximum first dominant wavelength among the first dominant wavelengths, a maximum second dominant wavelength among the second dominant wavelengths, and a maximum third dominant wavelength among the third dominant wavelengths; and a driving circuit configured to: drive one of the red, green, or blue sub-pixels in each pixel to emit light with full brightness and simultaneously drive another one or two of the sub-pixels to emit light with full brightness so that the color of light resulting from mixing corresponds to an adjusted dominant wavelength, and the adjusted dominant wavelengths are approximately equal.

In another aspect of the present disclosure, the red sub-pixel emits red light with full brightness having a red dominant wavelength, and the green sub-pixel within the same pixel emits green light with partial brightness having a green dominant wavelength so that the color of light resulting from mixing the red light and the green light corresponds to an adjusted red dominant wavelength, and the adjusted red dominant wavelength is closer to the minimum value among the first dominant wavelengths.

In another aspect of the present disclosure, the blue sub-pixel emits blue light with full brightness having a blue dominant wavelength, and the green sub-pixel within the same pixel emits green light with partial brightness having a green dominant wavelength so that the color of light resulting from mixing the blue light and the green light corresponds to an adjusted blue dominant wavelength, and the adjusted blue dominant wavelength is closer to the maximum value among the third dominant wavelengths.

In another aspect of the present disclosure, the green sub-pixel emits green light with full brightness having a green dominant wavelength, and the blue sub-pixel within the same pixel emits blue light with partial brightness having a blue dominant wavelength so that the color of light resulting from mixing the green light and the blue light corresponds to an adjusted green dominant wavelength, and the adjusted green dominant wavelength is closer to the average value among the second dominant wavelengths.

In another aspect of the present disclosure, the green sub-pixel emits green light with full brightness having a green dominant wavelength, and the red sub-pixel within the same pixel emits red light with partial brightness having a red dominant wavelength so that the color of light resulting from mixing the green light and the red light corresponds to an adjusted green dominant wavelength, and the adjusted green dominant wavelength is closer to the average value among the second dominant wavelengths.

### BRIEF DESCRIPTION OF THE DRAWINGS

In order to sufficiently understand the essence, advantages and the preferred embodiments of the present invention, the following detailed description will be more clearly understood by referring to the accompanying drawings.

FIGS. 1A and 1B are schematic diagrams illustrating a micro-LED display according to one embodiment of the present disclosure.

FIGS. 2A to 2C are wavelength diagrams illustrating color matching of red and green light according to one embodiment of the present disclosure.

FIGS. 3A to 3C are wavelength diagrams illustrating color matching of blue and green light according to one embodiment of the present disclosure.

FIGS. 4A to 4C are wavelength diagrams illustrating color matching of green and blue light according to one embodiment of the present disclosure.

FIGS. 5A to 5C are wavelength diagrams illustrating color matching of green and red light according to one embodiment of the present disclosure.

FIG. 6 is a flowchart illustrating a method for pixel chromaticity compensation according to one embodiment of the present disclosure.

### DETAILED DESCRIPTION OF THE INVENTION

The following description shows the preferred embodiments of the present invention. The present invention is described below by referring to the embodiments and the figures. Thus, the present invention is not intended to be limited to the embodiments shown but is to be accorded the principles disclosed herein. Furthermore, various modifications or changes in light thereof will be suggested to a person skilled in the art and are to be included within the spirit and purview of this application and scope of the appended claims.

In the present disclosure, terms such as first, second, and third are used to describe various elements, components, regions, layers, and/or sections. These elements, components, regions, layers, and/or sections should not be limited by these terms. These terms are only used to distinguish one element, component, region, layer, or section from another. Therefore, a first element, component, region, layer, or section discussed below could also be referred to as a second element, component, region, layer, or section without departing from the spirit of the present disclosure. As used herein, ‘approximately equal’ means equal within a tolerance such as ± 1%, 2%, and 5% that is sufficient to reduce perceivable chromaticity differences among pixels.

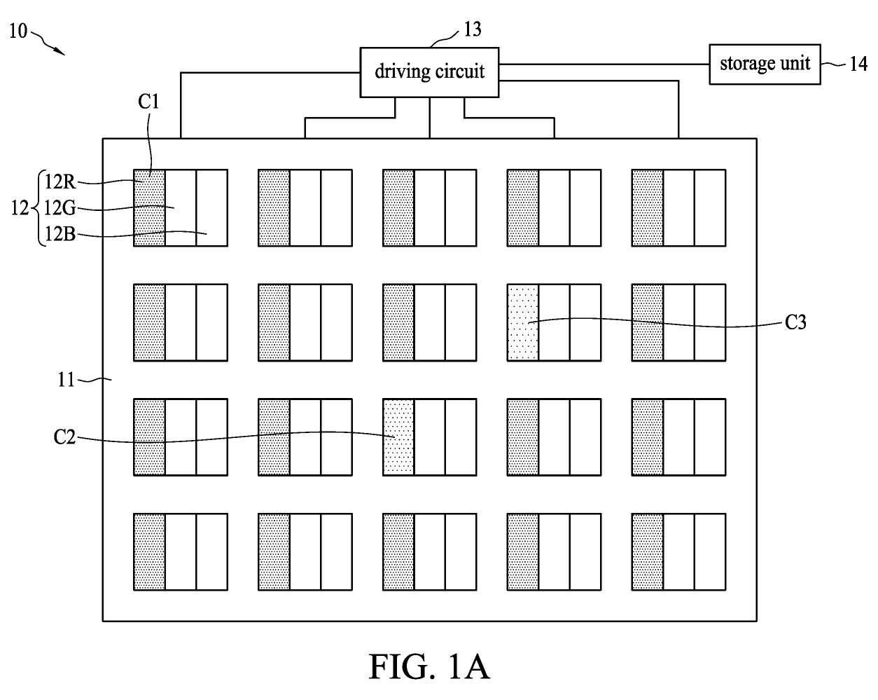

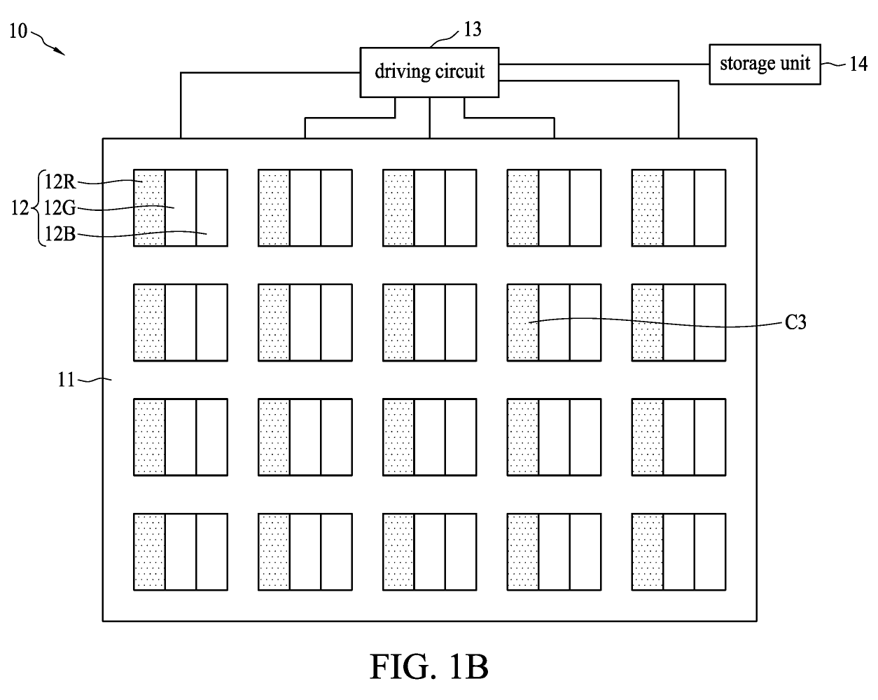

FIGS. 1A and 1B are schematic diagrams illustrating a micro-LED display according to one embodiment of the present disclosure. The display 10 includes a substrate 11, a plurality of pixels 12 disposed on the substrate 11, a driving circuit 13, and a storage unit 14. The driving circuit 13 drives the red sub-pixel 12R, green sub-pixel 12G, and blue sub-pixel 12B of each pixel 12 to emit light at full brightness sequentially (just the same sub-pixel emits light at any given time). Additionally, an optical instrument (not shown) measures the first dominant wavelength of the red sub-pixel 12R, the second dominant wavelength of the green sub-pixel 12G, and the third dominant wavelength of the blue sub-pixel 12B in each pixel 12. The positions of the sub-pixels and their corresponding dominant wavelengths are stored in the storage unit 14.

As shown in FIG. 1A, the red sub-pixels 12R in each pixel 12 of the display 10 are activated to emit light, while the green sub-pixels 12G and blue sub-pixels 12B remain unlit. As mentioned earlier, when adjacent pixels 12 display the same pure red light, the majority of red sub-pixels 12R emit red light with a chromaticity of C1. However, some red sub-pixels 12R emit red light with different chromaticities, such as C2 and C3.

Further referring to FIG. 1B, the driving circuit 13 drives the red sub-pixel 12R of each pixel 12 to emit red light at full brightness, which has a red dominant wavelength. Simultaneously, it drives the green sub-pixel 12G within the same pixel 12R to emit green light at partial brightness, which has a green dominant wavelength. The color matching of the mixed light from the red and green sub-pixels results in an adjusted red dominant wavelength. This adjusted red dominant wavelength approaches the minimum value of the first dominant wavelengths recorded in the storage unit 14, ensuring that the red light from each red sub-pixel 12R has a consistent chromaticity C3.

Likewise, when the blue sub-pixels 12B in each pixel 12 are driven to emit blue light at full brightness, and the green sub-pixels 12G in the same pixel 12 are driven to emit green light at partial brightness, the color matching of the mixed light from these sub-pixels will exhibit an adjusted blue dominant wavelength that approaches the maximum value among the third dominant wavelengths.

Furthermore, there are two ways for adjusting the color matching of the green light emitted by the green sub-pixels 12G, as follows: (1) When the green sub-pixels 12G in each pixel 12 are driven to emit green light at full brightness, and the blue sub-pixels 12B in the same pixel 12 are driven to emit blue light at partial brightness, the color matching of the mixed light will exhibit an adjusted green dominant wavelength that approaches the average value among the second dominant wavelengths; (2) When the green sub-pixels 12G in each pixel 12 are driven to emit green light at full brightness, and the red sub-pixels 12R in the same pixel 12 are driven to emit red light at partial brightness, the color matching of the mixed light will exhibit an adjusted green dominant wavelength that approaches the average value among the second dominant wavelengths.

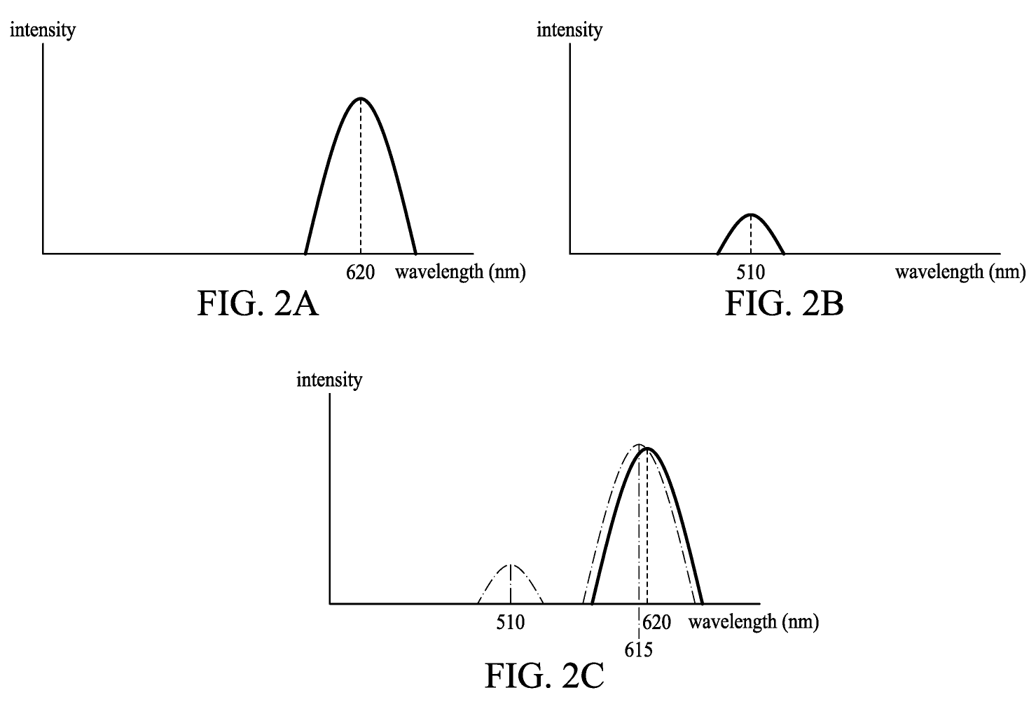

FIGS. 2A to 2C illustrate the wavelength diagrams of color matching after mixing red light and green light according to one embodiment of the present disclosure. FIG. 2A shows a red sub-pixel 12R emitting red light with a red dominant wavelength of 620 nm, while the green sub-pixel 12G in the same pixel 12 emits green light with a green dominant wavelength of 510 nm at partial brightness, as shown in FIG. 2B. Referring to FIG. 2C, the color matching of the mixed light from the red and green sub-pixels results in an adjusted red dominant wavelength of 615 nm, which is the minimum value among the first dominant wavelengths stored in the storage unit 14.

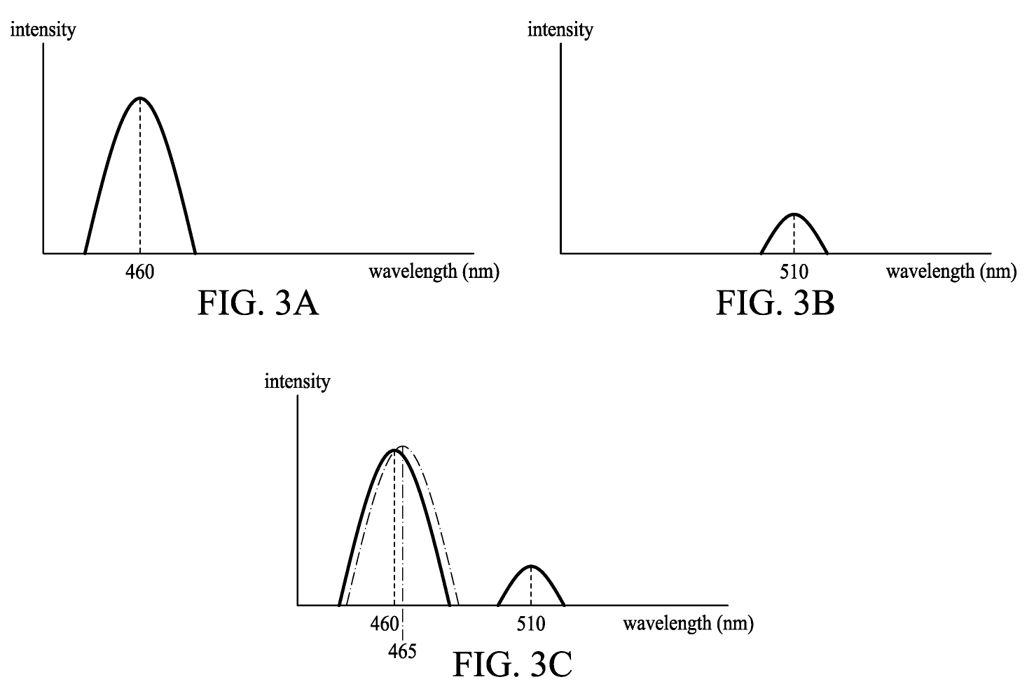

FIGS. 3A to 3C are wavelength diagrams of color matching after mixing blue light and green light according to one embodiment of the present disclosure. FIG. 3A shows that a blue sub-pixel 12B emits blue light with a blue dominant wavelength of 460 nm. A green sub-pixel 12G within the same pixel 12 emits green light with a green dominant wavelength of 510 nm at partial brightness, as shown in FIG. 3B. Referring to FIG. 3C, the color matching after mixing blue and green light is represented by an adjusted blue dominant wavelength of 465 nm, which is the maximum value among the third dominant wavelengths recorded in the storage unit 14.

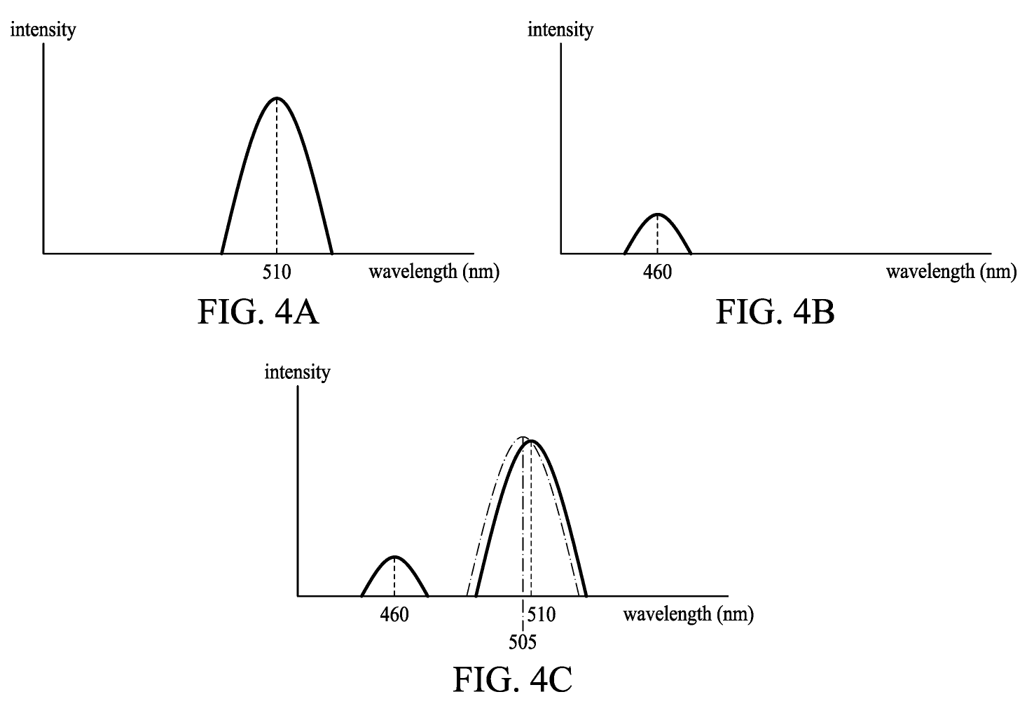

FIGS. 4A to 4C are wavelength diagrams of color matching after mixing green light and blue light according to one embodiment of the present disclosure. FIG. 4A shows a green sub-pixel 12G emits green light with a green dominant wavelength of 510 nm. A blue sub-pixel 12B within the same pixel 12 emits blue light with a blue dominant wavelength of 460nm at partial brightness, as shown in FIG. 4B. Referring to FIG. 4C, the color matching after mixing green and blue light is represented by an adjusted green dominant wavelength of 505 nm, which is the average value among the second dominant wavelengths recorded in the storage unit 14.

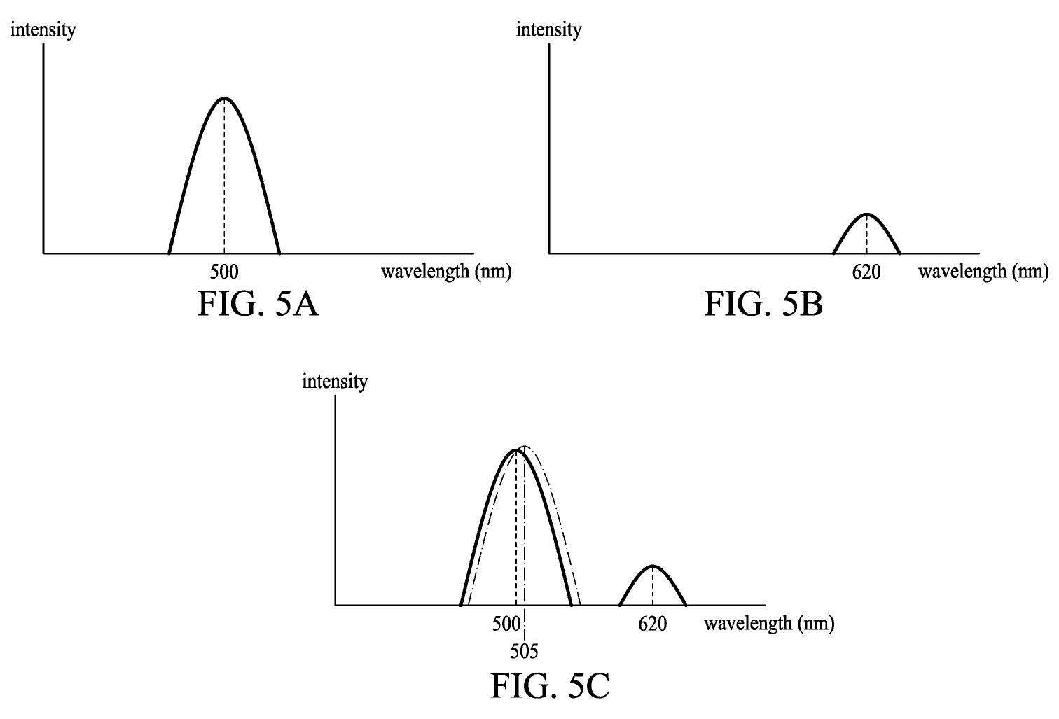

FIGS. 5A to 5C are wavelength diagrams of color matching after mixing green light and red light according to one embodiment of the present disclosure. FIG. 5A shows that a green sub-pixel 12G emits green light with a green dominant wavelength of 500 nm. A red sub-pixel 12R within the same pixel 12 emits red light with a red dominant wavelength of 620 nm at partial brightness, as shown in FIG. 5B. Referring to FIG. 5C, the color matching after mixing green and red light is represented by an adjusted green dominant wavelength of 505 nm, which is the average value among the second dominant wavelengths recorded in the storage unit 14.

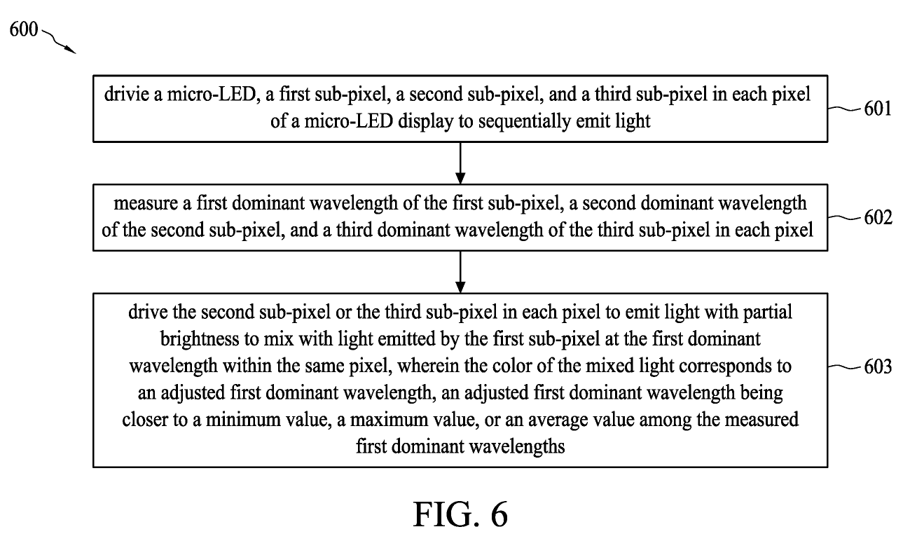

FIG. 6 is a flowchart depicting a method for pixel chromaticity compensation according to one embodiment of the present disclosure. In step 601 of the flowchart 600, the first, second, and third sub-pixels in each pixel of a micro-LED display are sequentially driven to emit light. In step 602, an optical instrument (not shown) is used to measure the first dominant wavelength of the first sub-pixel, the second dominant wavelength of the second sub-pixel, and the third dominant wavelength of the third sub-pixel. Additionally, the positions of each sub-pixel and the corresponding first, second, or third dominant wavelengths can be stored.

In step 603, the second or third sub-pixels in each pixel are driven to emit light at partial brightness to mix with the light emitted by the first sub- pixel at the first dominant wavelength. The color matching of the mixed light from the red and green sub-pixels results in an adjusted first dominant wavelength, which approaches the minimum, maximum, or average value of the measured first dominant wavelengths.

As described in the embodiment above, according to the operations in step 603, when the first sub-pixel is a red sub-pixel and the second sub-pixel is a green sub-pixel, the red sub-pixel emits red light with a red dominant wavelength, and the green sub-pixel in the same pixel emits green light at partial brightness with a green dominant wavelength. The color matching of the mixed light from the red and green sub-pixels results in an adjusted red dominant wavelength, which approaches the minimum value of the measured first dominant wavelengths.

Furthermore, according to the operations in step 603, when the first sub-pixel is a blue sub-pixel and the second sub-pixel is a green sub-pixel, the blue sub-pixel emits blue light with a blue dominant wavelength, and the green sub-pixel in the same pixel emits green light at partial brightness with a green dominant wavelength. The color matching of the mixed light from the blue and green sub-pixels results in an adjusted blue dominant wavelength, which approaches the maximum value of the measured first dominant wavelengths.

In addition, according to the operations of step 603, when the first sub-pixel is a green sub-pixel, the second sub-pixel is a blue sub-pixel, and the third sub-pixel is a red sub-pixel, the green sub-pixel emits green light with a green dominant wavelength, and the blue sub-pixel in the same pixel emits blue light with a blue dominant wavelength at partial brightness. The color matching of the mixed light from the green and blue light results in an adjusted green dominant wavelength, which approaches the average of the dominant wavelengths measured for each of the first sub-pixels. Alternatively, the green sub-pixel emits green light with a green dominant wavelength, and the red sub-pixel in the same pixel emits red light with a red dominant wavelength at partial brightness. The color matching of the light after mixing the green and red light will exhibit an adjusted dominant green wavelength, which approaches the average of the dominant wavelengths measured for each of the first sub-pixels.

Although the present invention is written with respect to specific embodiments and implementations, various changes and modifications may be suggested to a person having ordinary skill in the art. It is intended that the present disclosure encompasses such changes and modifications that fall within the scope of the appended claims.

What is claimed is:

1. A method of chroma compensation for pixels, comprising:
driving a first sub-pixel, a second sub-pixel, and a third sub-pixel in each pixel of a micro-LED display to sequentially emit light;
measuring a first dominant wavelength of the first sub-pixel, a second dominant wavelength of the second sub-pixel, and a third dominant wavelength of the third sub-pixel in each pixel; and
driving the second sub-pixel or the third sub-pixel in each pixel to emit light with partial brightness to mix with light emitted by the first sub-pixel at the first dominant wavelength within the same pixel, wherein the color of the mixed light corresponds to an adjusted first dominant wavelength;
wherein the adjusted first dominant wavelength is closer to a minimum value, a maximum value, or an average value among the measured first dominant wavelengths.

2. The method according to claim 1, wherein the first sub-pixel is a red sub-pixel and the second sub-pixel is a green sub-pixel, the red sub-pixel emits red light having a red dominant wavelength, the green sub-pixel within the same pixel emits green light with partial brightness having a green dominant wavelength so that the color of light resulting from mixing the red light and the green light corresponds to an adjusted red dominant wavelength and the adjusted red dominant wavelength is closer to the minimum value among the measured first dominant wavelengths.

3. The method according to claim 1, wherein the first sub-pixel is a blue sub-pixel and the second sub-pixel is a green sub-pixel, the blue sub-pixel emits blue light having a blue dominant wavelength, and the green sub-pixel within the same pixel emits green light with partial brightness having a green dominant wavelength so that the color of light resulting from mixing the blue light and the green light corresponds to an adjusted blue dominant wavelength, and the adjusted blue dominant wavelength is closer to the maximum value among the measured first dominant wavelengths.

4. The method according to claim 1, wherein the first sub-pixel is a green sub-pixel, the second sub-pixel is a blue sub-pixel, the third sub-pixel is a red sub-pixel, the green sub-pixel emits green light having a green dominant wavelength, and the blue sub-pixel within the same pixel emits blue light with partial brightness having a blue dominant wavelength so that the color of light resulting from mixing the green light and the blue light corresponds to an adjusted green dominant wavelength, and the adjusted green dominant wavelength is closer to the average value among the measured first dominant wavelengths.

5. The method according to claim 1, wherein the first sub-pixel is a green sub-pixel, the second sub-pixel is a blue sub-pixel, the third sub-pixel is a red sub-pixel, the green sub-pixel emits green light having a green dominant wavelength, and the red sub-pixel within the same pixel emits red light with partial brightness having a red dominant wavelength so that the color of light resulting from mixing the green light and the red light corresponds to an adjusted green dominant wavelength, and the adjusted green dominant wavelength is closer to the average value among the measured first dominant wavelengths.

6. A method of chroma compensation for pixels, comprising:
driving a first sub-pixel, a second sub-pixel, and a third sub-pixel in each pixel of a micro-LED display to sequentially emit light;
measuring a first dominant wavelength of the first sub-pixel, a second dominant wavelength of the second sub-pixel, and a third dominant wavelength of the third sub-pixel in each pixel; and
driving the second sub-pixel or the third sub-pixel in each pixel to emit light at a partial luminance to mix with light emitted by the first sub-pixel at the first dominant wavelength within the same pixel;
adjusting the first dominant wavelength by mixing the light emitted by the second sub-pixel or the third sub-pixel so that the adjusted first dominant wavelength is closer to a minimum value, a maximum value, or an average value among the measured first dominant wavelengths.

7. The method according to claim 6, wherein the first sub-pixel is a red sub-pixel and the second sub-pixel is a green sub-pixel, the red sub-pixel emits red light having a red dominant wavelength, the green sub-pixel within the same pixel emits green light with a partial luminance having a green dominant wavelength so that the color matching of the mixed light results in an adjusted red dominant wavelength, and the adjusted red dominant wavelength is closer to the minimum value among the measured first dominant wavelengths.

8. The method according to claim 6, wherein the first sub-pixel is a blue sub-pixel and the second sub-pixel is a green sub-pixel, the blue sub-pixel emits blue light having a blue dominant wavelength, and the green sub-pixel within the same pixel emits green light with a partial luminance having a green dominant wavelength so that the color matching of the mixed light results in an adjusted blue dominant wavelength, and the adjusted blue dominant wavelength is closer to the maximum value among the measured first dominant wavelengths.

9. The method according to claim 6, wherein the first sub-pixel is a green sub-pixel, the second sub-pixel is a blue sub-pixel, the third sub-pixel is a red sub-pixel, the green sub-pixel emits green light having a green dominant wavelength, and the blue sub-pixel within the same pixel emits blue light with a partial luminance having a blue dominant wavelength so that the color matching of the mixed light results in an adjusted green dominant wavelength, and the adjusted green dominant wavelength is closer to the average value among the measured first dominant wavelengths.

10. The method according to claim 6, wherein the first sub-pixel is a green sub-pixel, the second sub-pixel is a blue sub-pixel, the third sub-pixel is a red sub-pixel, the green sub-pixel emits green light having a green dominant wavelength, and the red sub-pixel within the same pixel emits red light with a partial luminance having a red dominant wavelength so that the color matching of the mixed light results in an adjusted green dominant wavelength, and the adjusted green dominant wavelength is closer to the average value among the measured first dominant wavelengths.

11. A micro light-emitting diode (micro-LED) display comprising:
a plurality of pixels, each pixel including a red sub-pixel, a green sub-pixel, and a blue sub-pixel;
a storage unit configured to store a first dominant wavelength of the red sub-pixel, a second dominant wavelength of the green sub-pixel, and a third dominant wavelength of the blue sub-pixel for each pixel; and
a driving circuit configured to:
drive one of the red, green, or blue sub-pixels in each pixel to emit light with full brightness and drive another one or two of the sub-pixels to emit light with full brightness so that the color of light resulting from mixing corresponds to an adjusted dominant wavelength, and the adjusted dominant wavelengths are approximately equal.

12. The display according to claim 11, wherein the red sub-pixel emits red light with full brightness having a red dominant wavelength, and the green sub-pixel within the same pixel emits green light with partial brightness having a green dominant wavelength so that the color of light resulting from mixing the red light and the green light corresponds to an adjusted red dominant wavelength, and the adjusted red dominant wavelength is closer to the minimum value among the first dominant wavelengths.

13. The display according to claim 11, wherein the blue sub-pixel emits blue light with full brightness having a blue dominant wavelength, and the green sub-pixel within the same pixel emits green light with partial brightness having a green dominant wavelength so that the color of light resulting from mixing the blue light and the green light corresponds to an adjusted blue dominant wavelength, and the adjusted blue dominant wavelength is closer to the maximum value among the third dominant wavelengths.

14. The display according to claim 11, wherein the green sub-pixel emits green light with full brightness having a green dominant wavelength, and the blue sub-pixel within the same pixel emits blue light with partial brightness having a blue dominant wavelength so that the color of light resulting from mixing the green light and the blue light corresponds to an adjusted green dominant wavelength, and the adjusted green dominant wavelength is closer to the average value among the second dominant wavelengths.

15. The display according to claim 11, wherein the green sub-pixel emits green light with full brightness having a green dominant wavelength, and the red sub-pixel within the same pixel emits red light with partial brightness having a red dominant wavelength so that the color of light resulting from mixing the green light and the red light corresponds to an adjusted green dominant wavelength, and the adjusted green dominant wavelength is closer to the average value among the second dominant wavelengths.

16. The display according to claim 11, wherein the first dominant wavelengths of the red sub-pixels, the second dominant wavelengths of the green sub-pixels, and the third dominant wavelengths of the blue sub-pixels for all pixels are measured when the red sub-pixels, the green sub-pixels, and the blue sub-pixels in each pixel are sequentially activated at full brightness.

17. The display according to claim 12, wherein the adjusted dominant wavelength is closer to the minimum value among the first dominant wavelengths.

18. The display according to claim 11, wherein the adjusted dominant wavelength is closer to the maximum value among the third dominant wavelengths.

19. The display according to claim 11, wherein the adjusted dominant wavelength is closer to the average value among the second dominant wavelengths.

20. The display according to claim 19, wherein the adjusted dominant wavelength is an adjusted green dominant wavelength.
